(19) United States
(12) Patent Application Publication
(10) Pub. No.: US 2017/0071063 A1
(43) Pub. Date: Mar. 9, 2017

(54) ELECTRONIC EQUIPMENT HOUSINGS WITH INTEGRATED ELECTRONIC CARD GUIDES, ELECTROMAGNETIC INTERFERENCE (EMI) SHIELDING, AND THERMAL COOLING

(71) Applicant: Ross Video Limited, Iroquois (CA)

(72) Inventor: Donald Mark Sizemore, Virginia Beach, VA (US)

(73) Assignee: Ross Video Limited, Iroquois (CA)

(21) Appl. No.: 14/847,165

(22) Filed: Sep. 8, 2015

(51) Int. Cl. H05K 5/00; H05K 9/00; H05K 5/02

(52) U.S. Cl. CPC H05K 5/003; H05K 5/0213; H05K 5/0247; H05K 9/0081

(57) ABSTRACT

An electronic equipment housing structural panel includes an integrated electronic card guide formed in the structural panel. The panel may also include and an integrated ElectroMagnetic Interference (EMI) shielding and thermal cooling structure formed in the structural panel. The EMI shielding and thermal cooling structure is in the form of apertures in one embodiment, and the apertures provide for convective heat transfer from the panel to air flowing through the apertures. In an electronic equipment housing, a pair of such panels are parallel to each other but spaced apart from each other with their card guides facing each other. An electronic card may then be installed in the card guides. In an embodiment, a structural panel is produced by forming the integrated electronic card guide, and the integrated EMI shielding and thermal cooling structure if provided, in a blank of material.

### FIELD

The present disclosure relates generally to electronic equipment housings and, in particular, to such housings with integrated electronic card guides, ElectroMagnetic Interference (EMI) shielding, and thermal cooling.

### BACKGROUND

Suppression of unwanted emission of ElectroMagnetic Interference (EMI) from electronic devices is desirable in order to prevent these devices from impacting the function of other electronic devices and the reception of useful radio transmissions. Acceptable levels of EMI emissions are legislated in most areas of the world, and are therefore an important consideration in the design of any electronic equipment. Additionally, it is desirable to shield internal electronic equipment components from possible interference from external sources.

An important aspect of EMI suppression in many electronic systems involves shielding of the internal components by an enclosure. Common practice involves constructing a Faraday cage around components which have high levels of EMI emission. A Faraday cage is a continuous structure which surrounds components with a mesh on all sides. The mesh is constructed of a conductive material and held at a common potential (usually a system's ground). Any radiated electromagnetic radiation which attempts to pass through the cage is instead partially or fully conducted through the cage and therefore the energy level of EM radiation which passes through the cage is reduced or eliminated. The cage serves to both protect components inside the cage from external EM radiation, as well as prevent unwanted EM radiation generated by the components inside the cage to escape. Gaps, holes, and openings in a Faraday cage must be sized, in all 3 dimensions, based upon the maximum frequency of the EM radiation to be suppressed. Thus, as the operating frequency of the components increases, the wavelength is reduced, and therefore the cage openings must be reduced in size. There are standard calculations that are commonly used to determine the maximum allowable size of openings.

Typical rack-mount electronic equipment, for which EMI suppression may be desirable, also provides internal mechanical support for one or more circuit boards or electronic cards. Such cards are typically installed parallel to one another in either a horizontal or vertical manner. Parallel mounting allows for cooling air to be moved across all cards in the system. The direction of airflow may be front-to-back, top-to-bottom, or side-to-side, depending upon the configuration of the cards within the electronic equipment or chassis.

Current systems provide card guides which hold a card in the correct position, and may also act as an aid to installing cards, by allowing the card to be slid in and out along the card guides. These card guides are typically implemented using plastic channels, formed metal channels, plastic moldings, or other elements that are attached to the equipment housing.

### SUMMARY

An electronic equipment housing structural panel includes an integrated electronic card guide formed in the structural panel and an integrated EMI shielding and thermal cooling structure formed in the structural panel.

Such an electronic equipment housing structural panel could include multiple integrated electronic card guides formed in the structural panel. The integrated electronic card guides could include respective channels formed in respective card guide areas of the structural panel. The integrated EMI and thermal cooling structure could then be formed in an area of the structural panel different from the respective card guide areas.

The electronic equipment housing structural panel could include multiple integrated EMI and thermal cooling structures formed in the structural panel, in the form of respective sets of apertures formed in the structural panel, for example. In an embodiment, each of the apertures has a depth of 11.5 mm and a diameter in a range of 5.5 mm to 8.0 mm. Each aperture has an axial surface area of at least 198.7 mm². in another embodiment. In a further embodiment, each of the sets of apertures is formed in a respective area of the structural panel, and an aperture density of each of the sets of apertures is at least 65% of a total surface area of the respective area.

An electronic equipment housing includes a first pair of structural panels; and a second pair of structural panels. The structural panels in the first pair of structural panels are spaced apart from each other and oriented parallel to each other by the structural panels in the second pair of structural panels, and each of the structural panels in the second pair of structural panels includes an electronic equipment housing structural panel as described above, with the card guides in the structural panels in the second pair of structural panels facing each other and extending in a direction parallel to a plane of each structural panel in the first pair of structural panels.

Electronic equipment includes the electronic equipment housing described above, and an electronic card installed in the card guides of the structural panels in the second pair of structural panels.

The electronic equipment could also include a further electronic card that has a thermal conductor coupled to the structural panels in the second pair of structural panels.

In an embodiment, the electronic equipment also includes one or both of: a heat spreader attached to the electronic card; and a further heat spreader attached to the further electronic card.

The further electronic card could include a printed circuit board. The thermal conductor coupled to the structural panels in the second pair of structural panels could then include one or more of: an exposed copper plane on a surface of the printed circuit board; internal ground planes in the printed circuit board; vias in the printed circuit board; and fasteners that fasten the further electronic card to the structural panels in the second pair of structural panels.

A method of manufacturing an electronic equipment housing structural panel includes forming, in a blank of material for the electronic equipment housing structural panel, an integrated electronic card guide; and forming, in the blank of material, an integrated EMI shielding and thermal cooling structure.

Forming the integrated electronic card guide could involve machining the integrated electronic card guide in the blank of material.

Forming the integrated electronic card guide could involve forming a plurality of integrated electronic card guides in the blank of material.

In an embodiment, forming the integrated EMI and thermal cooling structure involves machining apertures in the blank of material.

The machining could involve one of: punching the apertures in the blank of material, drilling the apertures in the blank of material and laser cutting the apertures in the blank of material.

Another method involves providing a first pair of structural panels; providing a second pair of structural panels, each structural panel in the second pair of structural panels comprising: an integrated electronic card guide formed in the panel, and an integrated EMI shielding and thermal cooling structure formed in the structural panel; and attaching the structural panels in the first pair of structural panels to the structural panels in the second pair of structural panels. The panels are attached with the structural panels in the first pair of structural panels spaced apart from each other and oriented parallel to each other by the structural panels in the second pair of structural panels, and the electronic card guides in the structural panels in the second pair of structural panels facing each other and extending in a direction parallel to a plane of each structural panel in the first pair of structural panels.

The method could also include installing an electronic card into the electronic card guides of the structural panels in the second pair of structural panels.

In an embodiment, the method includes thermally coupling a further electronic card to the structural panels in the second pair of structural panels, in an orientation perpendicular to the electronic card guides of the structural panels in the second pair of structural panels.

According to another aspect of the present disclosure, an electronic equipment housing structural panel includes an integrated electronic card guide formed in the structural panel.

Other aspects and features of embodiments of the present disclosure will become apparent to those ordinarily skilled in the art upon review of the following description.

### BRIEF DESCRIPTION OF THE DRAWINGS

Examples of embodiments of the invention will now be described in greater detail with reference to the accompanying drawings.

FIG. 1 illustrates a cross-section of a housing structural panel with a surface-mounted card guide.

FIG. 2 illustrates a cross-section of an example housing structural panel with an integrated electronic card guide.

FIGS. 2A and 2B are cross-sectional views of an example housing structural panel and electronic circuit card illustrating conductive and convective heat transfer.

FIGS. 3 and 4 are isometric views of another example electronic equipment housing structural panel.

FIG. 5A is a plan view toward an interior surface of the example structural panel of FIG. 3, and FIGS. 5B to 5E are bottom, top, left side, and right side plan views, respectively, according to the orientation shown in FIG. 5A.

FIGS. 6 and 7 are isometric views of another example electronic equipment housing structural panel.

FIG. 8A is a plan view toward an interior surface of the example structural panel of FIG. 6, and FIGS. 8B to 8E are bottom, top, left side, and right side plan views, respectively, according to the orientation shown in FIG. 8A.

FIG. 9 is an isometric view of an example electronic card.

FIG. 10 is an exploded view of the example electronic card of FIG. 9.

FIGS. 11A and 11B are isometric views of example electronic equipment.

FIGS. 12A and 12B are exploded partial views of the example electronic equipment of FIGS. 11A and 11B.

FIGS. 13 and 14 are top and bottom isometric views of an example heat spreader.

FIGS. 15 and 16 are flow charts of example methods.

### DETAILED DESCRIPTION

The present application relates to electronic equipment, and especially high-speed digital rack-mounted electronic equipment. Such equipment might be utilized for telecommunications and/or broadcast, for example. Aspects of the application relate to an approach to chassis design, which provides for EMI suppression, while simultaneously providing heat dissipation for thermal cooling of internal components. Further aspects of the application also relate to managing internal space for electronic cards.

In the present application, an electronic card is intended to refer to a printed circuit board or other substrate or base, in combination with integrated and/or surface-mounted components such as processors, memory devices, connectors, etc. Electronic equipment, also referred to herein as a chassis, includes a housing or enclosure that is constructed out of structural panels, and one or more electronic cards installed in the housing. A chassis could include additional components, such as one or more cooling fans, one or more cover plates, and/or brackets to attach the chassis to an equipment rack. A housing need not necessarily be entirely closed around the electronic equipment. A cover plate, for example, could be separate from the housing and close the front and/or back of the equipment. In one embodiment, a cover plate covers the back of the equipment, and a connector plate carried by an electronic card covers part of the front of the equipment.

As noted above, current systems provide card guides that are typically implemented using plastic channels, formed metal channels, plastic moldings, or other elements that are attached to the equipment housing. Card guides are typically located inside an equipment housing, and thus reduce the maximum size of a card that can be accommodated, as well as the usable space on that card. Furthermore, simple card guides formed from bent sheet metal or molded plastic are generally fairly imprecise, requiring larger physical tolerances (i.e., unoccupied areas) in the cards which they carry. This is undesirable not only because of the useful space reduction, but also because the larger physical tolerances can hinder blind-mating of cards due to excessive play in the position of a card as it sits in the card guide.

Regarding EMI suppression, as noted above the wavelength to be suppressed is reduced as the operating frequency of shielded components increases, and any openings in a Faraday cage must also be reduced in size. This provides a challenge to designers of electronic systems, as it reduces the allowable tolerance on unwanted gaps in the Faraday cage. Also, it is often desirable to place holes or gaps in a Faraday cage to allow for servicing, adjustment, interconnection of cables or pipe (such as a heat pipe or a fluid pipe), airflow for cooling, and so on.

In particular, as operating frequencies increase, openings for airflow must be made smaller, presenting significant challenge to the thermal design of electronic systems. Due to surface/skin effects, a set of smaller holes is less efficient at allowing air to pass than a set of larger holes having the same total cross-sectional area as the set of smaller holes. To compensate for this, systems attempt to increase airflow by providing higher air velocity and pressure, or by increasing the overall cross-sectional area of the airflow. Additional techniques, including ducting, fluid-cooling systems, and complicated heat spreaders may also be used. This can result in higher system cost, larger overall system size, and additional power consumption by the cooling system, as well as greater acoustic noise.

Aspects of the present application relate to chassis design using integrated card guides that are formed in housing structural panels. Manufacturing techniques such as computer-controlled or computer-assisted machining may provide for greater precision in card guides and/or increased available space inside a housing. EMI suppression could also or instead be integrated into an equipment housing, along with thermal cooling that may provide improved airflow and conductive heat sinks.

In some embodiments, the diameter of holes or apertures is increased to facilitate airflow. Larger aperture diameter is possible by making the apertures deeper in one embodiment, or in other words by using a thicker structural panel for the housing. In a traditional Faraday cage, the thickness of panels that make up the cage is much less than the diameter of any apertures, and the EMI suppression is dominantly determined by the diameter. In general, the aperture diameter in a thin-walled cage should not be more than 1/10th of the wavelength of the highest frequency that is to be suppressed. This provides adequate suppression of the fundamental, 3rd, and 5th harmonics.

Shielding effectiveness (SE, expressed in dB) can be determined by the aperture size and is determined by rearranging:

$$d = \frac{10 x}{\frac{SE \text{/} K}{2}}$$

$$into$$

$$SE = \frac{K 20 x}{d}$$

where x is the frequency in meters, K is a shielding factor (20 for rectangular or square apertures, 40 for round apertures), and d is aperture diameter for round apertures or slot length for rectangular or square apertures.

A further factor which must be considered is the number of apertures. As the number of round apertures doubles, the SE decreases by 3 dB. For example, a housing structural panel with 32 round apertures of diameter d will have a 15 dB reduction in SE compared to a structural panel with only 1 round aperture of diameter d.

If the design of the apertures is treated as a waveguide, however, additional suppression is possible. By increasing the depth of the apertures, these openings function as a waveguide below cutoff (WGBC) and provide significant reduction in EMI emissions below the cutoff frequency. Conversely, a constant EMI suppression can be maintained with a larger aperture diameter.

The cutoff frequency for a round aperture, for example, is approximated by:

$${f}_{c} = \frac{1.8412 c}{π d}$$

where f_{c} is the cutoff frequency, c is the speed of light and d is the diameter of the aperture.

Conversely, the maximum diameter of a round aperture for a given cutoff frequency is:

$$d = \frac{1.8412 c}{π {f}_{c}}$$

For example, for a system running at 12 GHz, the maximum round aperture size should not exceed a diameter of 14.6 mm.

The cutoff frequency for a rectangular aperture, for example, is approximated by:

$${f}_{c} = \frac{c}{2 a}$$

Where f_{c} is the cutoff frequency, c is the speed of light and a is the cross-sectional area of the rectangular aperture.

Conversely, the maximum area of a rectangular aperture for a given cutoff frequency is:

$$a = \frac{c}{2 {f}_{c}}$$

The additional shielding effectiveness for a waveguide below cutoff for round apertures can be approximated as:

$$Δ SE = 32 \frac{depth}{width}$$

So, for example a housing panel with depth (thickness) of 12 mm and round aperture diameter of 7 mm will have an SE improvement of approximately 55 dB, compared to the same round aperture in a 1.2 mm thick panel, which will only see an improvement of 5.5 dB.

For a rectangular or square aperture, shielding effectiveness for a waveguide below cutoff can be approximated as:

$$Δ SE = 24 \frac{depth}{width}$$

where width is the length of the longest side of the rectangle.

Aperture size and depth, and number of apertures, can be used to determine a maximum aperture size while still meeting target EMI suppression at desired frequencies. An aperture in a thick-walled structural panel can have a greater diameter than an aperture in a thin-walled panel while still providing effective EMI suppression, due to the increased wall thickness and resultant increased aperture depth. Physical characteristics of aperture diameter, depth, and number can thus be selected according to the foregoing equations to arrive at a combination that achieves EMI suppression or shielding that meets a target or requirement, as set out in technical or safety standards for example.

In order to make apertures in a housing structural panel deeper, thickness of the structural panel would be increased. However, making the walls of an equipment housing thicker would normally reduce the maximum size of the internal cards in the equipment. Forming grooves in a structural panel to form the card guides avoids the need for surface-mounted card guides and can thus provide for a maximum card width similar to that of a thin-walled housing.

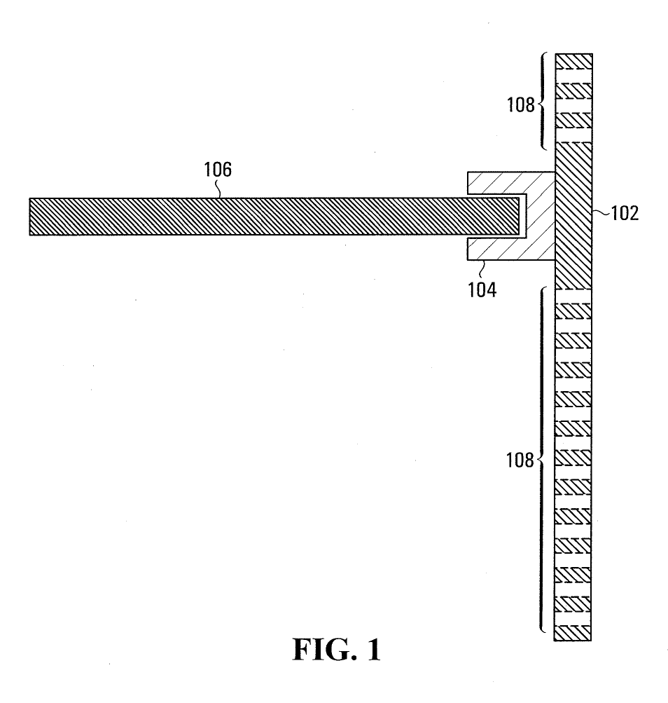

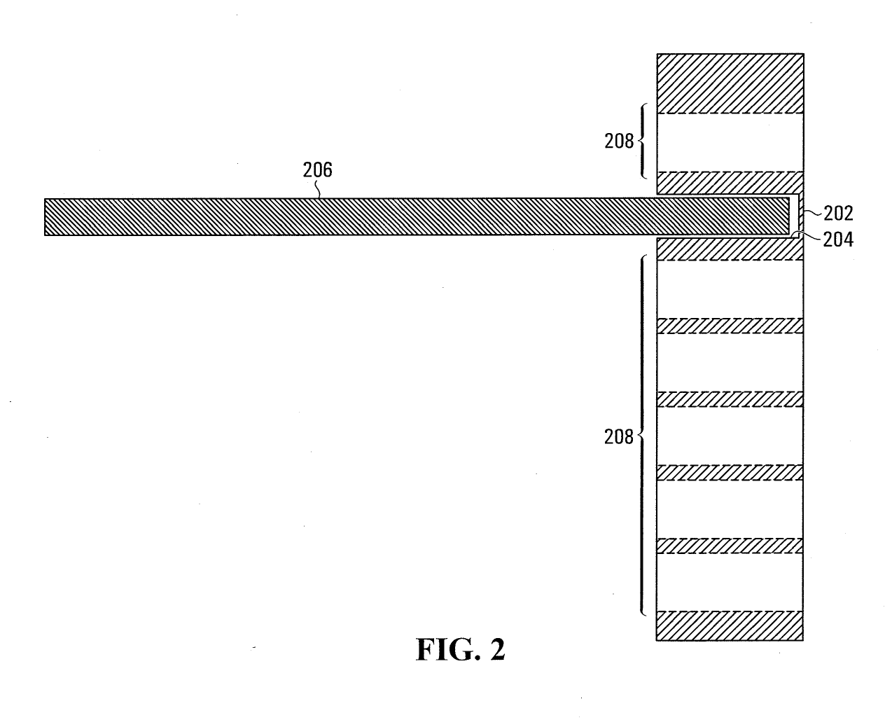

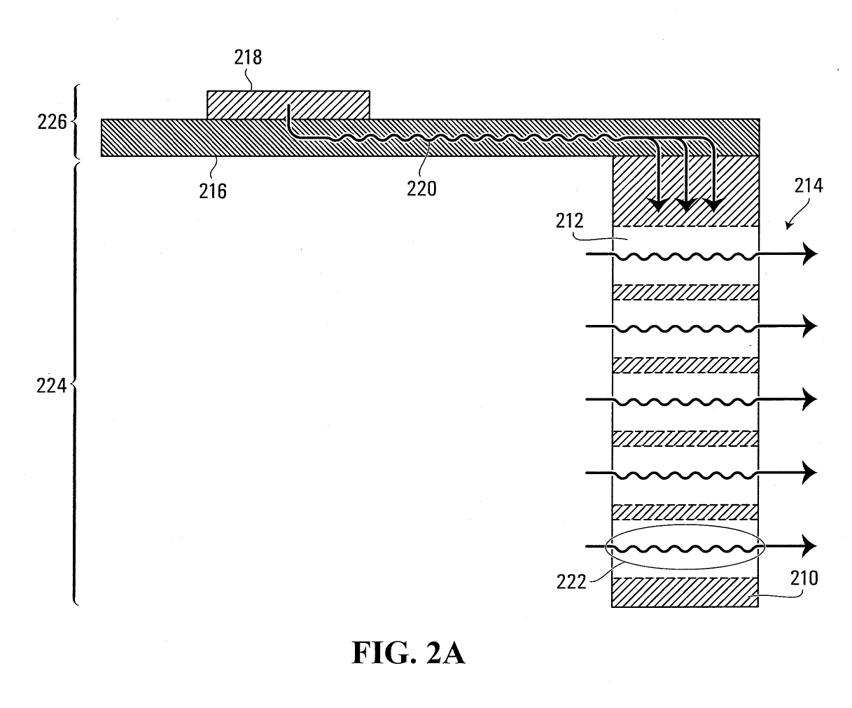

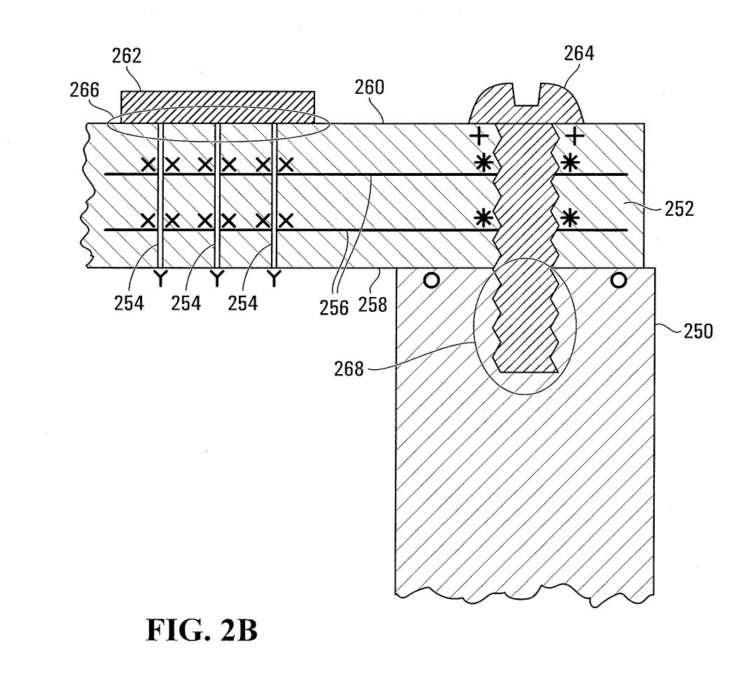

This can be seen perhaps most clearly by comparing FIGS. 1 and 2. FIG. 1 illustrates a cross-section of a housing structural panel with a surface-mounted card guide, and FIG. 2 illustrates a cross-section of an example structural panel with an integrated electronic card guide. The structural panel 102 in FIG. 1 has a card guide 104, mounted on a surface that would face the interior of an electronic equipment housing, for holding an electronic card 106. A counterpart card guide would also be provided at a left-hand side of the electronic card 106, so that the electronic card can be guided into the electronic equipment housing and supported after installation. Such card guides might be oriented horizontally when equipment is mounted in a rack, for example, and in that case the card guides provide vertical support for the electronic card 106. The depth of the card guide 104 and the thickness of the part of the card guide that attaches to the structural panel 102 reduce the amount of usable space on the electronic card 106. As noted above, simple card guides formed from bent sheet metal or molded plastic are generally fairly imprecise, requiring further physical tolerances in the electronic cards which they carry, further reducing usable “real estate” on the electronic card 106.

Referring now to FIG. 2, the example structural panel 202 has an integrated card guide 204 formed in the panel instead of surface-mounted to the panel. With a thicker structural panel 202 relative to the panel 102, surface-mounting a card guide would further reduce the maximum size and usable space on an electronic card 206 unless the size of the equipment housing were otherwise increased. However, integrating the card guide 204 into the panel 202 effectively recovers space on the electronic card 206 that would otherwise be unavailable with a surface-mounted card guide. In addition, a machining process to form a channel or groove into a blank of material for the structural panel 202 to form the card guide 204 may be more accurately controllable than bending or molding processes that are typically used to form surface-mounted card guides, so the card guide 204 could potentially be manufactured with tighter tolerances which provide less “play” of the electronic card 206 in the card guide 204. The tighter tolerances might reduce the amount of area on the electronic card 206 that must remain unoccupied in order to provide clearance for the card guide 204 relative to a less precise surface-mounted card guide, and could also assist with blind-mating of the electronic card 206 during installation.

Due to the increased thickness of the structural panel 202 relative to the structural panel 102 (FIG. 1), it is possible to increase the ratio of the cross-sectional area of holes to material in the panel, while still maintaining adequate strength for the panel to be used as a structural panel of an equipment housing. A thinner panel such as 102 requires a greater cross-sectional area of material to provide sufficient mechanical strength to the chassis. This is illustrated in FIGS. 1 and 2 by the sizes of the apertures 108, 208. Solely for the purposes of illustration, the apertures 208 in FIG. 2 are four times the size of the apertures 108 in FIG. 1. The six apertures 208 in FIG. 2 provide the same overall open surface area as 24 of the apertures having the smaller diameter as shown in FIG. 1. However, providing 24 apertures in the panel 102 in FIG. 1 could weaken the panel too much for it to be used as a structural element in an equipment housing. The larger overall open surface area of the larger apertures 208 in FIG. 2 may allow a freer flow of air through the structural panel 202 relative to the panel 102, and thus provide more effective cooling than a thin panel (with a greater cross-sectional area of material and less open area) when fed air from a fan of equal capacity. Put another way, the same thermal cooling or heat dissipation could potentially be provided with a larger overall open surface area but a smaller fan.

FIGS. 1 and 2 are not intended to be drawn to any particular absolute scale, or any relative scale with respect to each other. Electronic equipment housings are often fabricated from panels that are only 1-2 mm thick, whereas in an embodiment the example structural panel 202 has a thickness of 11-12 mm. These are intended only as examples. Other thicknesses are possible, and thickness, aperture size, and the number of apertures can be selected based on EMI suppression targets. Therefore, these physical characteristics of a structural panel and its apertures may vary between different embodiments.

Due to the increased thickness of the panel 202, the airflow holes (apertures 208) themselves have significant axial surface area. This can effectively transform an aperture wall into a thermal radiator. As thermal transfer between media is related to the temperature difference, surface area, and air velocity, increasing the surface area of the inside of the apertures 208 themselves may provide for significant heat transfer from the panel 202 to the passing air.

Thermal transfer between air and a solid material through convective heat flow can be approximated through Newton's cooling law:

Q=hAΔT

where Q is the heat flow, h is a heat transfer coefficient, A is the surface area and ΔT is the temperature differential between the air and solid. Therefore, the heat flow increases in a directly proportional manner to the surface area of the solid. In one embodiment, components which create significant heat may be conductively coupled to the panel 202, and the heat is then dissipated though convective thermal transfer to the air passing through the apertures 208 in the panel. By increasing the thickness of the panel 202 and thus the depth of the apertures 208, the surface area available for convective heat transfer increases, making it possible to reduce the airflow required for cooling while maintaining the same level of heat dissipation. This could in turn reduce the size and/or number of fans, the overall acoustic noise, and power requirement of the thermal cooling system for electronic equipment. This could also allow components for which providing direct airflow cooling within equipment may be inconvenient conductively transfer heat to the apertures.

For example, “hot” electronic components in the electronic card 206 could conductively transfer heat to the ground plane(s) within a printed circuit board, directly or through attached heat spreaders and/or heat pipes, for example. It is typical for up to 70%-90% of heat generated by surface-mounted components to be transferred to the printed circuit board. If the ground plane(s) and/or heat spreader(s)/pipe(s) are thermally coupled to the thick chassis panel 202, then there would be an additional mechanism to transfer heat from the electronic components to cooling airflow.

FIGS. 2A and 2B are cross-sectional views of an example housing structural panel and electronic circuit card illustrating conductive and convective heat transfer.

In FIG. 2A, a structural panel 210 has apertures 212 which accommodate airflow 214 through the panel. An electronic card which includes a heat-producing component 218 mounted on a printed circuit board 216 is thermally coupled to the structural panel 210. Such thermal coupling could be simply through physical contact between the printed circuit board 216 and the structural panel 210, or through a thermal interface material. In the example shown, the apertures 212 allow for airflow in the region 224, but for illustrative purposes in this example there is no “direct” cooling airflow for the component 218 in the region 226.

Heat is transferred from the component 218 to the printed circuit board 216, and then to the structural panel 210 through conductive heat transfer, represented at 220. This heat is dissipated to the air flowing through the apertures 212 through convective heat transfer, represented at 222. This illustrates how convective heat transfer and conductive heat transfer could be used to aid in cooling of a component such as 218, by indirect transfer of heat to an airflow in the region 224, when it might not be convenient or possible to provide for more direct cooling of the component using an airflow in the region 226.

Conductive heat transfer between such a printed circuit board and a chassis structural panel could be enhanced by exposing copper planes on the surfaces of the board, and/or by thermally coupling holes through the circuit board to internal and external ground planes. Such holes could include circuit board vias, and/or holes that are used to capture fasteners (such as screws) which couple the circuit board to a chassis. This could provide enhanced conductive transfer of heat, from the copper planes in the circuit board and through the fastener for instance, to the chassis. This is shown by way of example in FIG. 2B.

In FIG. 2B, as in FIG. 2A, an electronic card that has a heat-producing component 262 mounted on a printed circuit board 252 is thermally coupled to a structural panel 250. The structural panel 250 could also include one or more apertures to accommodate airflow. In order to avoid congestion in the drawing, such apertures are not shown in FIG. 2B. A fastener 264, shown as a screw in this example, passes through a hole in the printed circuit board 252 and is received in a bore in the structural panel 250 to attach the printed circuit board to the panel.

The printed circuit board 252 also has vias 254, internal copper planes 256, and external copper planes 258, 260. There are several types of conductive heat transfer represented in FIG. 2B, including:
conductive heat transfer 266, from the component 262 to the printed circuit board 252, vias 254, and external copper plane 260;
conductive heat transfer “X”, from the vias 254 to the internal copper planes 256;
conductive heat transfer “Y”, from the vias 254 to the external copper plane 258;
conductive heat transfer “+”, from the external plane 260 to the fastener 264;
conductive heat transfer “*”, from the internal copper planes 256 to the fastener 264;
conductive heat transfer “◯”, from the external copper plane 258 to the structural panel 250; and
conductive heat transfer 268, from the fastener 264 to the structural panel 250.

Such conductive heat transfer aids in dissipating heat from the component 262. The structural panel 250 could also include one or more apertures to provide for convective heat transfer to an airflow, thereby providing another heat transfer mechanism to dissipate heat from the component 262.

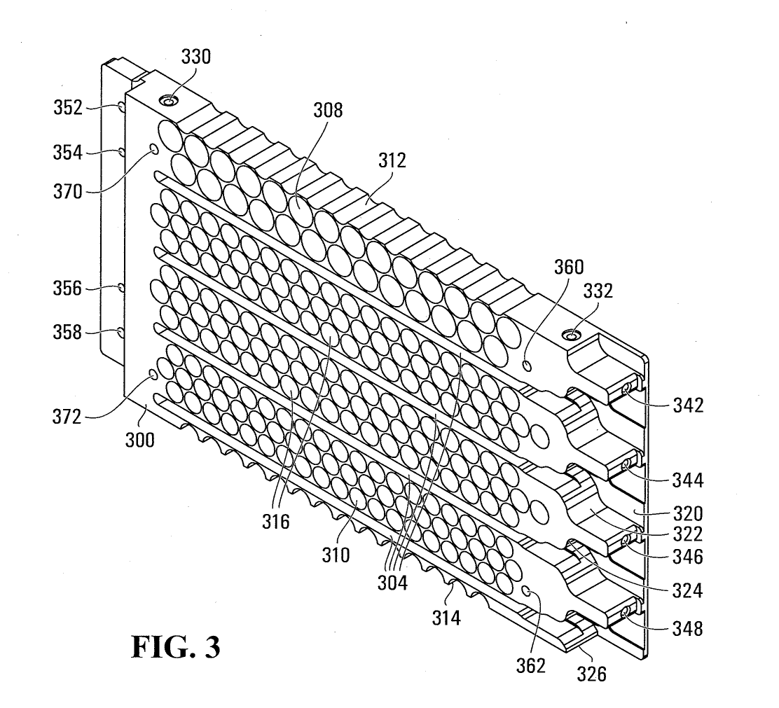

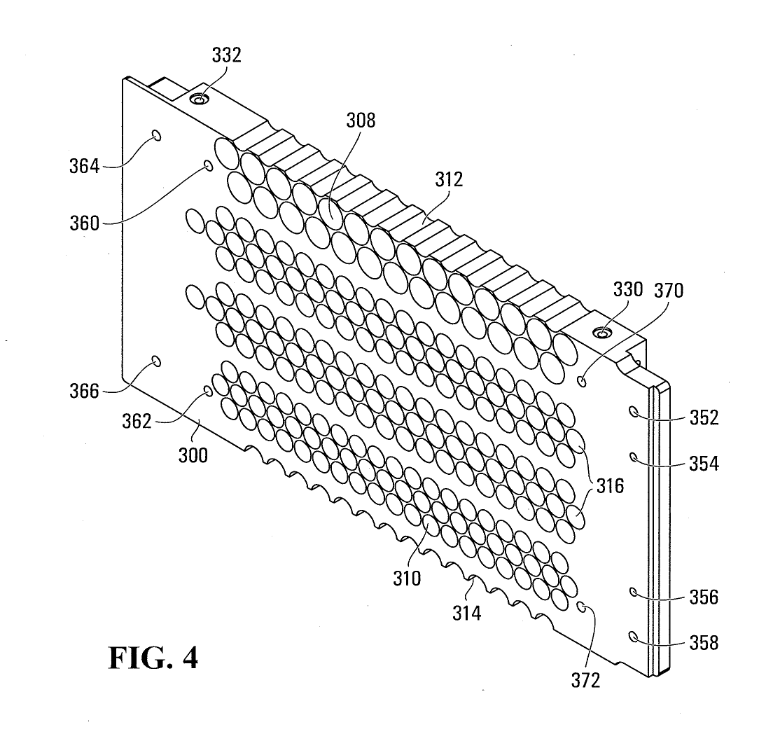

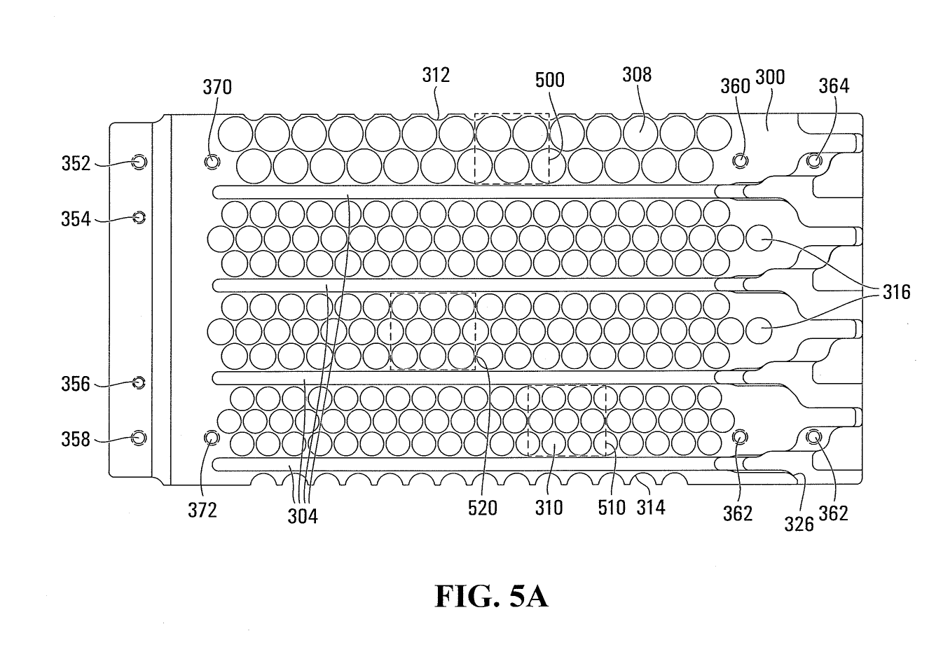

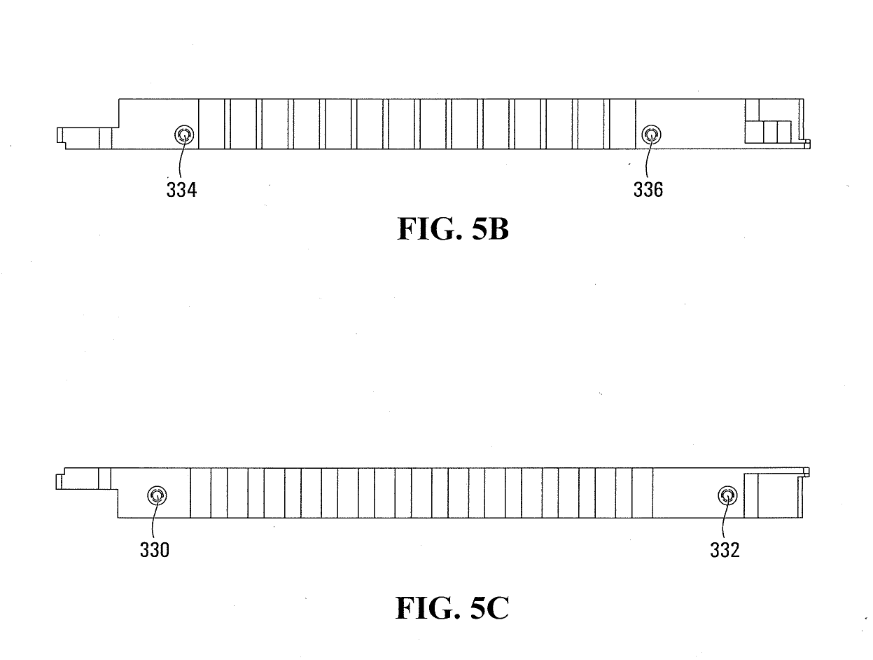

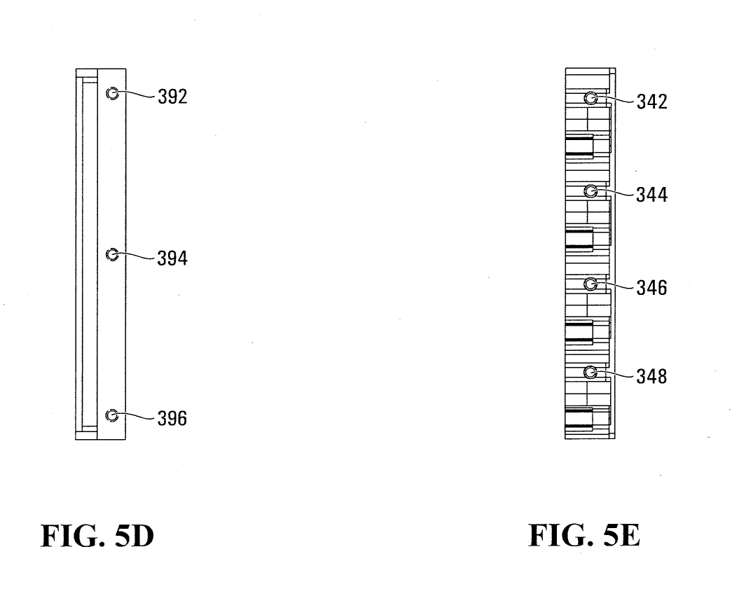

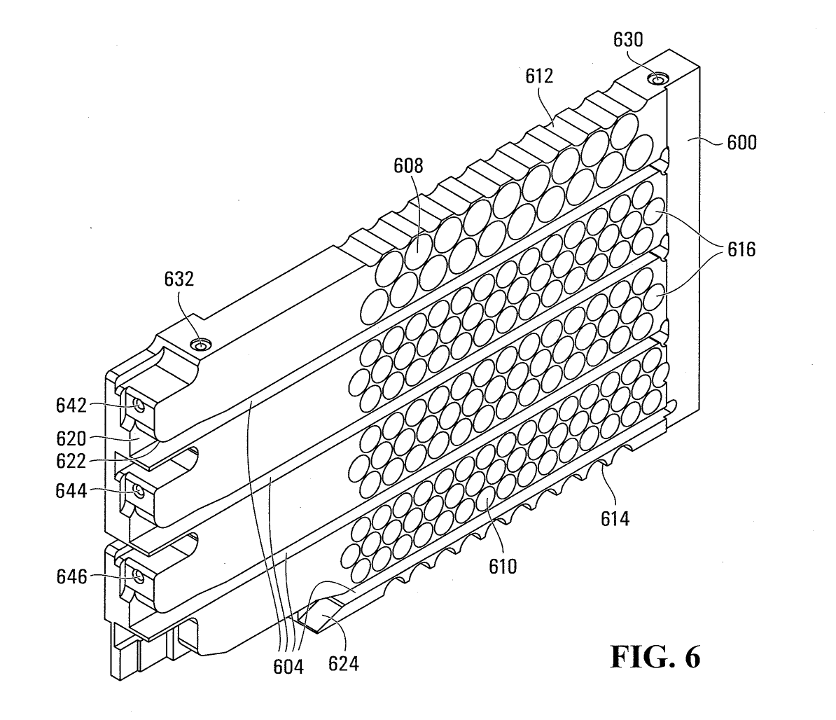

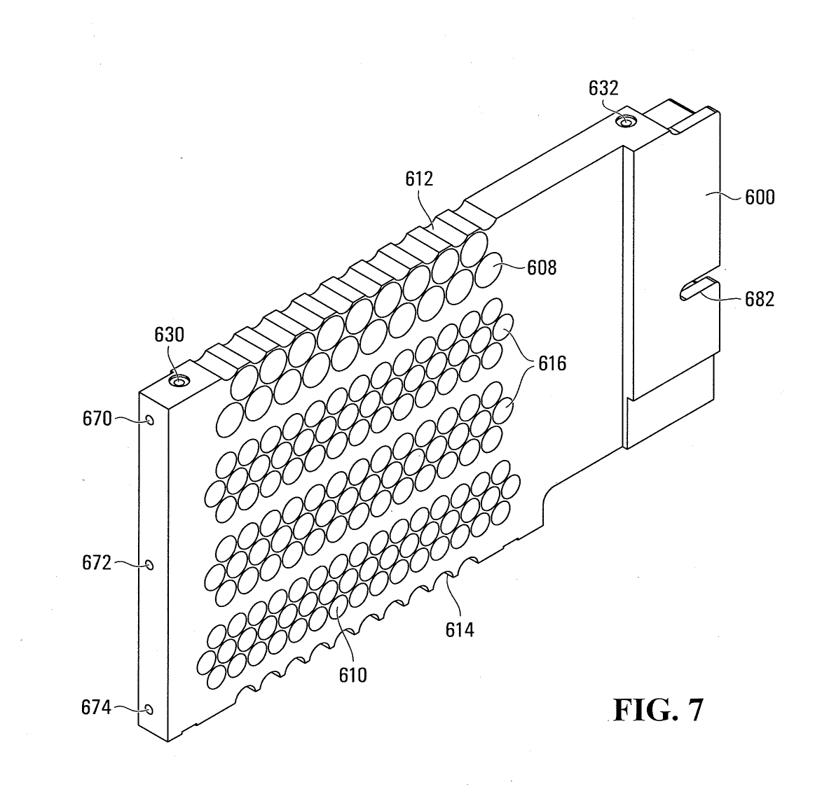

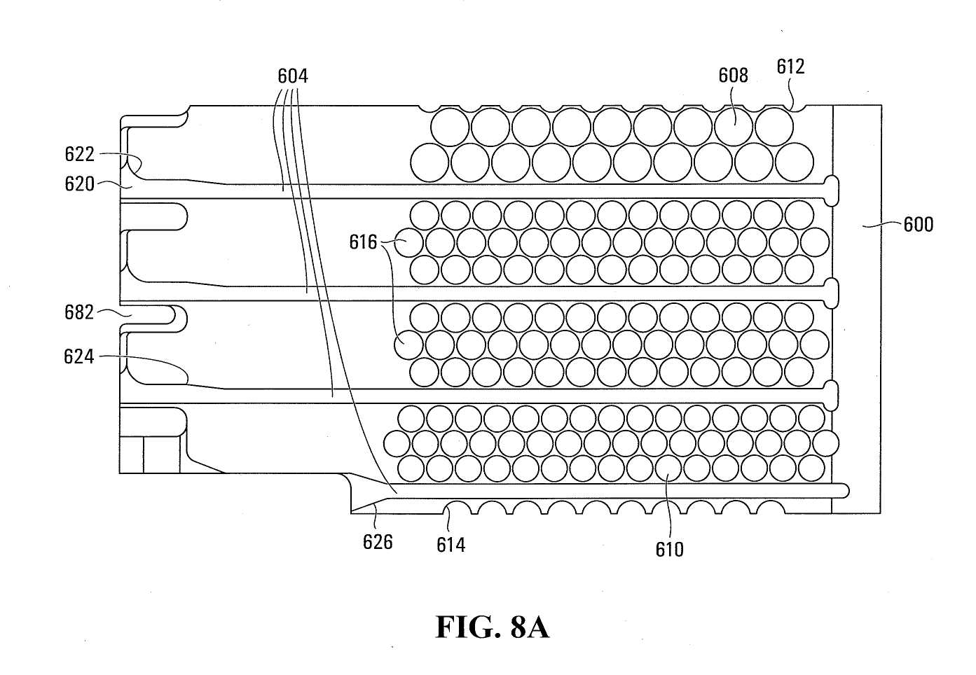

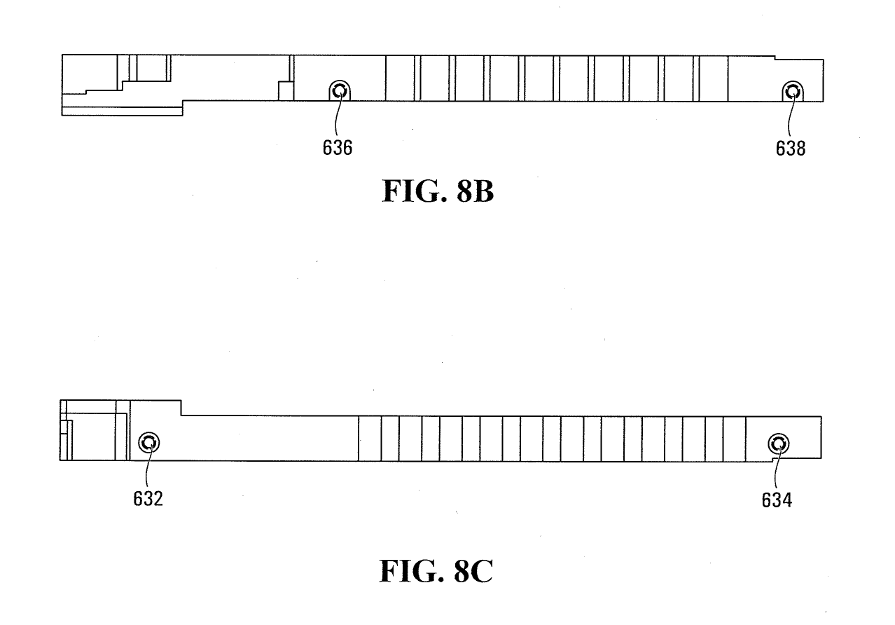

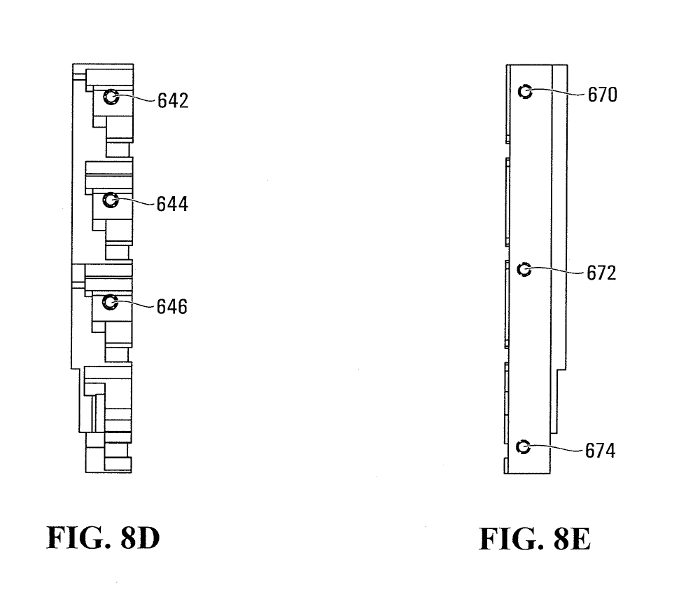

Example electronic equipment housing structural panels are illustrated in detail in FIGS. 3 to 8E. FIGS. 3 and 4 are isometric views of another example electronic equipment housing structural panel. The view in FIG. 3 is toward an interior surface that would be oriented inside the equipment housing, or at least toward a part of the interior of the housing in which electronic cards are to be installed. FIG. 4 is an isometric view toward a surface that would be oriented outside the housing or away from an electronic card part of the housing. FIG. 5A is a plan view of the example structural panel of FIG. 3 toward the interior surface, and FIGS. 5B to 5E are bottom, top, left side, and right side plan views, respectively, according to the orientation shown in FIG. 5A. FIGS. 6 and 7 are isometric views of another example electronic equipment housing structural panel. The view in FIG. 6 is toward an interior surface that would be oriented inside the equipment housing, or at least toward a part of the interior of the housing in which electronic cards are to be installed. FIG. 7 is an isometric view toward a surface that would be oriented outside the housing or away from an electronic card part of the housing. FIG. 8A is a plan view of the example structural panel of FIG. 6 toward the interior surface, and FIGS. 8B to 8E are bottom, top, left side, and right side plan views, respectively, according to the orientation shown in FIG. 8A.

With reference to FIGS. 3 to 5E, the example electronic equipment housing structural panel 300 includes an integrated electronic card guide formed in the structural panel, and an integrated EMI shielding and thermal cooling structure, formed in the structural panel. In an embodiment, the structural panel 300 is fabricated from aluminum. Although other materials could potentially be used, aluminum may be preferred for its light weight compared to other metals, and its thermal conduction properties. Further possible options for fabricating structural panels are described below.

In the example shown, there are four card guides 304, although in other embodiments there could be more or fewer card guides depending on the number of electronic cards that the electronic equipment housing is intended to accommodate. There are also multiple integrated EMI shielding and thermal cooling structures in the example structural panel 300. Each of the sets of apertures 308 and 310, and each of the sets of apertures 316, forms an integrated EMI shielding and thermal cooling structure. Partial apertures 312, 314 could also be provided to accommodate additional airflow.

Features such as a wider opening and chamfered surfaces 322, 324 of each card guide 304 toward the front panel end in FIG. 3 may aid in installation of an electronic card by guiding card edges into the card guides 304. During electronic card installation, a leading edge of an electronic card would be placed into the card guide opening 320, slid along one of the chamfered surfaces 322, 324, and then slid along the card guide 304 until it reaches an installed position. For the lower card guide 304 in FIGS. 3 and 5A, this initial guidance of an electronic card into the card guide could involve a lower housing wall, and the electronic card could be slid along the lower housing wall until it reaches the chamfered edge 324 of the lower card guide, and then into and along the card guide.

A stop could be provided, in a card guide 304, elsewhere on an equipment housing, and/or on an electronic circuit card or other component, to limit how far an electronic card is inserted.

As is perhaps most evident in FIGS. 3 and 5A, the integrated electronic card guides 304 are in the form of respective channels (one per card guide) formed in respective areas of the structural panel 300. The areas where the card guides are formed are referred to herein as card guide areas. The integrated EMI and thermal cooling structures are formed in areas of the structural panel 300 that are different from the respective card guide areas. Since the card guide areas already include channels or grooves to form the card guides 304, it may be preferable to avoid weakening the card guide areas with additional apertures. In an embodiment, the card guides 304 are 3 mm wide and 9 mm deep. This is an example only, as other card guide widths and/or depths could be used in other embodiment, depending on the dimensions of the electronic card(s) that are to be accommodated. More generally, different sizes and/or shapes of card guides could be provided in different structural panels. A single structural panel could similarly have different card guides with different sizes and/or shapes.

The apertures 308, 310 have different diameters from the apertures 316 in the example shown. In an embodiment, the apertures 308 each have a diameter of 8.0 mm, the apertures 310 and the partial apertures 312 each have a diameter of 5.5 mm, and the apertures 316 and the partial apertures 314 each have a diameter of 6.0 mm. Thus, a structural panel may have integrated EMI shielding and thermal cooling structures that have different physical characteristics. Multiple integrated EMI shielding and thermal cooling structures in a structural panel could all have the same physical characteristics in other embodiments, or there could be a different combination of structures with different physical characteristics.

In one embodiment, the structural panel 300 is 11.5 mm thick, and thus aperture depth is also 11.5 mm. In combination with the range in aperture diameter of 5.5 mm to 8.0 mm, this has been found to provide acceptable EMI suppression for electronic cards operating at 12 GHz. Axial surface area of each aperture would then be between

π×5.5 mm×11.5 mm=198.7 mm²,

and

π×8.0 mm×11.5 mm=289.0 mm²,

either of which is expected to be greater than the surface area along a direction of airflow through a thin-walled housing panel.

For example, a typical thin-walled housing panel might have a panel thickness of 1.5 mm, and the surface area for 5.5 mm and 8.0 mm diameter apertures in such a panel would be:

π×5.5 mm×1.5 mm=25.9 mm²

and

π×8.0 mm×1.5 mm=37.7 mm².

Regarding aperture “density”, as noted above a thicker structural panel may include more apertures than a thin-walled panel while still retaining sufficient strength to be used as a structural panel. In an embodiment, each of the apertures 308 has a diameter of 8.0 mm, the spacing between apertures is 8.5 mm on-center (or 0.5 mm between adjacent aperture edges), and the “height” of the integrated EMI shielding and thermal cooling structure formed by the apertures 308 in FIG. 5A (i.e., above the upper card guide 304) is 16.3 mm. Therefore, the apertures are arranged more closely than in a regular square or rectangular grid, since the height of the integrated EMI shielding and thermal cooling structure formed by the apertures 308 is less than the minimum distance of 16.5 mm that would be occupied by two adjacent apertures (twice the diameter of 8.0 mm plus the 0.5 mm edge-to-edge separation).

Taking an arbitrary rectangular block 500 (FIG. 5A) as an example, the block area includes an “open” cross-sectional area equivalent to a set of 4 adjacent apertures 308, including the area of one full aperture and the area of two half-apertures in the top row of apertures and the area of two full apertures in the bottom row. Thus, the total cross-sectional “open” surface area is approximately

4×π×(d/2)²=π×d²=π×(8.0 mm)²=201.1 mm²

and the total surface area of the block 500 is

width×height=(2×spacing)×height=17.0 mm×16.3 mm=277.1 mm²,

which gives an aperture or open area density of approximately

201.1 mm²/277.1 mm²×100%=72.6%.

Repeating these calculations for the arbitrary block 510 in the integrated EMI shielding and thermal cooling structure formed by the apertures 310 with a height between the top of the lower card guide 304 and a bottom of the next higher card guide 304 of 18.2 mm, an aperture diameter of 5.5 mm, and 6.0 mm spacing on-center, the total cross-sectional “open” area is approximately

9×π×(5.5/2)²=213.8 mm²

and the total area of the block 510 is approximately

width×height=(3×spacing)×height=18.0 mm×18.2 mm=327.6 mm²,

which gives an aperture or open area density of approximately

213.8 mm²/382.2 mm²×100%=65.3%.

Repeating these calculations for the arbitrary block 520 in one of the integrated EMI shielding and thermal cooling structure formed by the apertures 316 with a height between the top of the second-lowest card guide 304 in the view of FIG. 5A and a bottom of the next higher card guide 304 of 18.4 mm, an aperture diameter of 6.0 mm, and 6.5 mm spacing, the total cross-sectional “open” area is approximately

9×π×(6/2)²=254.5 mm²

and the total area of the block 52 is approximately

height×base=(3×spacing)×height=18.0 mm×18.4 mm=331.2 mm²,

which gives an aperture or open area density of approximately

254.5 mm²/331.2 mm²×100%=76.8%.

In each case, the aperture density within an integrated EMI shielding and thermal cooling structure is more than 65%.

Furthermore, in this embodiment, the aperture size is 8.0 mm with a spacing of 8.5 mm. Thus, the minimum material separation between apertures is 0.5 m, with a panel thickness of 11.5 mm. This provides a cross-sectional area of material between apertures of 5.75 mm². In a thin-walled housing panel, where for example the panel thickness is 1.5 mm, a similar aperture pattern would yield a cross-sectional area of material between apertures of only 0.75 mm². This would yield a panel which is significantly structurally weaker than the thicker panel made of the same material.

The dimensions noted above are for illustrative purposes. Such dimensions are implementation-dependent, and may vary depending on the dimension(s) of the electronic card(s) to be accommodated in a chassis.

Referring now to FIGS. 6 to 8E, the example electronic equipment housing structural panel 600, like the example panel 300, includes an integrated electronic card guide formed in the structural panel, and an integrated EMI shielding and thermal cooling structure, also formed in the structural panel. In the example shown, there are four card guides 604, although in other embodiments there could be more or fewer card guides depending on the number of electronic cards that the electronic equipment housing is intended to accommodate. There are also multiple integrated EMI shielding and thermal cooling structures in the example structural panel 600. Each of the sets of apertures 608 and 610, and each of the sets of apertures 616, forms an integrated EMI shielding and thermal cooling structure. Partial apertures 612, 614 could also be provided to accommodate additional airflow.

The integrated EMI shielding and thermal cooling structures in the structural panel 600 do not cover as much of the panel as those in the structural panel 300, illustrating another characteristic of structural panels that could vary between different embodiments. In one embodiment, the example structural panel 600 is designed to be located adjacent to cooling fans, and the integrated EMI shielding and thermal cooling structures might only cover the area(s) over which the cooling fans draw or exhaust cooling air.

Features such as a wider opening and chamfered surfaces 622, 624, 626 of each card guide 604 toward the front panel end in FIG. 6 may aid in installation of an electronic card by guiding card edges into the card guides 604. As noted above, a stop could be provided, in a card guide 604, elsewhere on an equipment housing, and/or on an electronic circuit card or other component, to limit how far an electronic card is inserted.

As in the example structural panel 300, the integrated electronic card guides 604 in the structural panel 600 are in the form of respective channels (one per card guide) formed in respective card guide areas of the structural panel 600, and the integrated EMI and thermal cooling structures are formed in areas of the structural panel 600 that are different from the respective card guide areas.

The apertures 608, 610 are of a different size from the apertures 616, and in one embodiment, the apertures 608, 610, 616 are of the same sizes as the example sizes noted above for apertures 308, 310, 316, respectively. In an embodiment, the structural panel 600 is 11.5 mm thick, and in this case the axial surface area of each aperture is as noted by way of example above with reference to FIGS. 3 to 5E.

In an embodiment, the example structural panels 300, 600 are used as opposite panels in an electronic equipment housing, and distances between corresponding card guides in the structural panels are the same. Aperture density in areas in which the sets of apertures are formed could then be as noted above by way of example.

The card guides 304/604 and sets of apertures 308/608, 310/610, 316/616 are relevant to aspects of the present application that relate to integrating card guides and EMI shielding and thermal cooling structures into electronic equipment housing structural panels. The example structural panels 300, 600 include other features as well. For example, the structural panel 300 includes various bores 330, 332, 334, 336, 342, 344, 346, 348, 352, 354, 356, 358, 360, 362, 364, 366, 370, 372, 392, 394, 396, which could be used in combination with fasteners such as screws or rivets to fasten the structural panel to other parts of electronic equipment. The structural panel 300 could be a side housing panel, for example, and be screwed to top and bottom housing walls during equipment assembly using some of the bores shown in FIGS. 3 to 5E. A chassis bracket and/or other component could similarly be attached or mounted to the structural panel 300 using other bores. Similarly, the various bores 630, 632, 634, 636, 642, 644, 646, 670, 672, 674 shown in FIGS. 6 to 8E could be used to attach or mount any of various components to the structural panel 600. In an embodiment, the structural panels 300, 600 are assembled as opposite panels of an equipment housing.

The example structural panels 300, 600 have different structures, but could be used as opposite panels in the same equipment housing. The example structural panel 600 has a channel 682 (FIG. 7), that could be provided to accommodate part of another component that is installed in an equipment chassis, whereas the example structural panel 300 does not include such a channel. The shape of the closed ends of the upper three card guides 604 in the view shown in FIG. 8A is different from those of the other card guides, but again the different structural panels could still be used as opposite panels in the same equipment housing. It should be appreciated, however, that structural panels that are more similar to each other could be used. Opposite structural panels could be mirror images of each other, for example. A single structural panel design with a symmetrical arrangement of card guides and EMI shielding/thermal cooling structures could instead be used, in which case opposite structural panels are identical.

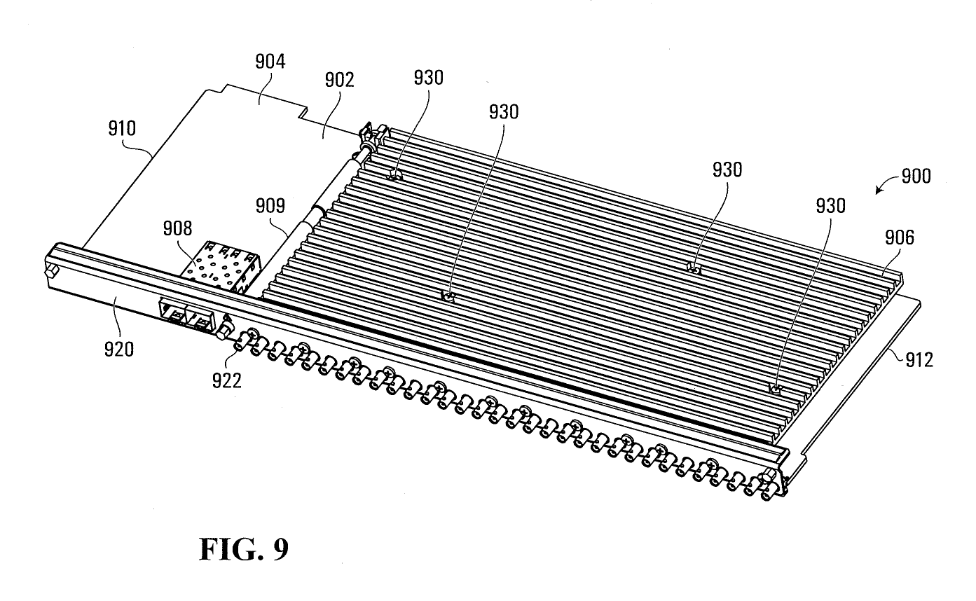

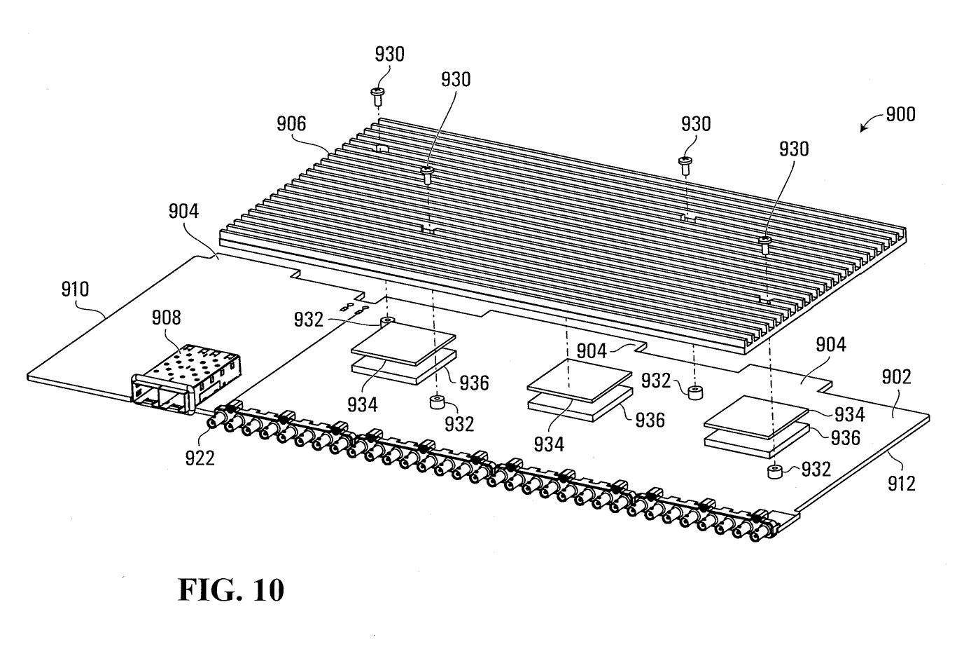

FIG. 9 is an isometric view of an example electronic card, and FIG. 10 is an exploded view of the example electronic card of FIG. 9. The example electronic card 900 includes a printed circuit board 902, with connectors 904 through which the printed circuit board can be connected to off-board components. In an embodiment, the connectors 904 mate with mating connectors in an equipment chassis when the electronic card 900 is installed.

In the example shown, the electronic card 900 has a connector housing 908, a retainer element 909 which releasably retains the card in its installed position, and a heat spreader 906 attached with screws 930. The screws 930 pass through bores in the heat spreader 906 and engage posts 932 which are attached to the printed circuit board, as shown in FIG. 10. A cover plate 920 is attached to the electronic card 900, and additional connectors 922 are also provided, to enable external components to be connected to the electronic card.

Underneath the heat spreader 906, electronic components 936 are mounted to the printed circuit board 902. Although three components 936 are shown, there may be fewer or more components in an actual implementation, and these components could include multiple components of the same type or components of different types. In order to avoid congestion in the drawing, three components of the same shape and size are shown, solely for the purposes of illustration. Thermal pads 934 facilitate heat transfer from the components 936 to the heat spreader 906 for dissipation. Such heat transfer need not be dependent upon the thermal pads 934, as there would still be some heat transfer from the components 936 to the heat spreader 906 through air, but in some embodiments the thermal pads may improve thermal conduction between the components and the heat spreader.

With reference to FIGS. 3, 6, and 9, for illustrative purposes consider an implementation in which the electronic card 900 is to be installed in a housing horizontally, between the structural panels 600 and 300 on opposite sides of an equipment housing. An installer would lift the electronic card 900 to place the leading ends of the board edges 910, 912 (toward the rear of the views in FIGS. 9 and 10) into the openings of corresponding card guides 604, 304, and then push the electronic card into the housing. In an embodiment, the connectors 904 mate with mating connectors that are arranged on a further electronic card that is located perpendicular to the card guides 604, 304. Card insertion could be complete when the connectors 904 bottom out in the mating connectors, or one or more separate stops could be used to limit card insertion. When the example electronic card 900 is fully inserted, the cover plate 920 covers an opening in the housing through which the electronic card was installed.

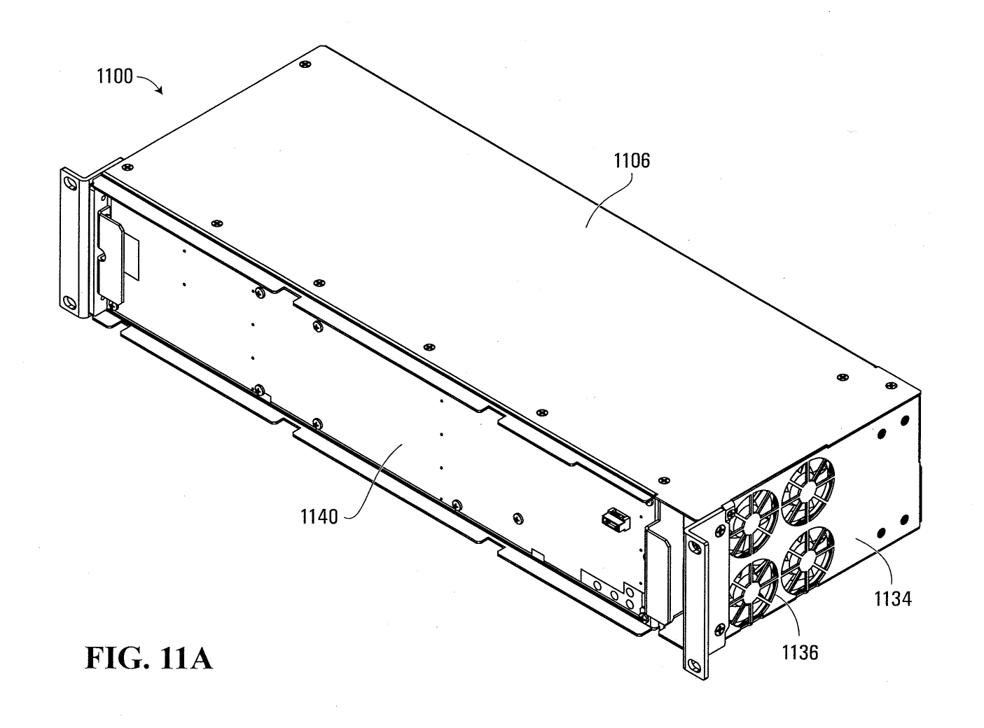

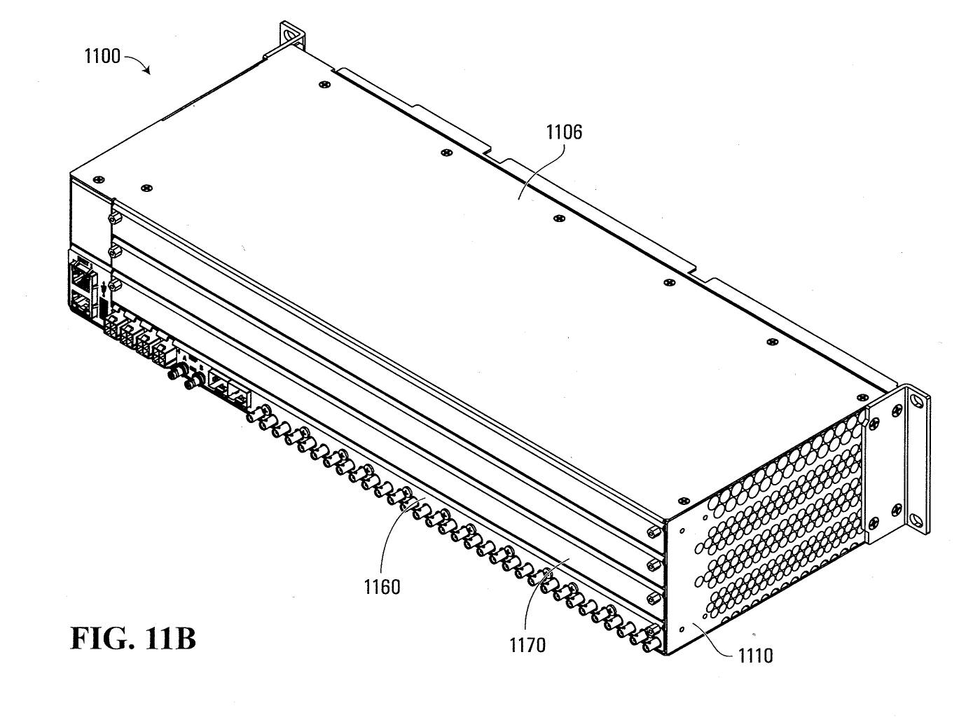

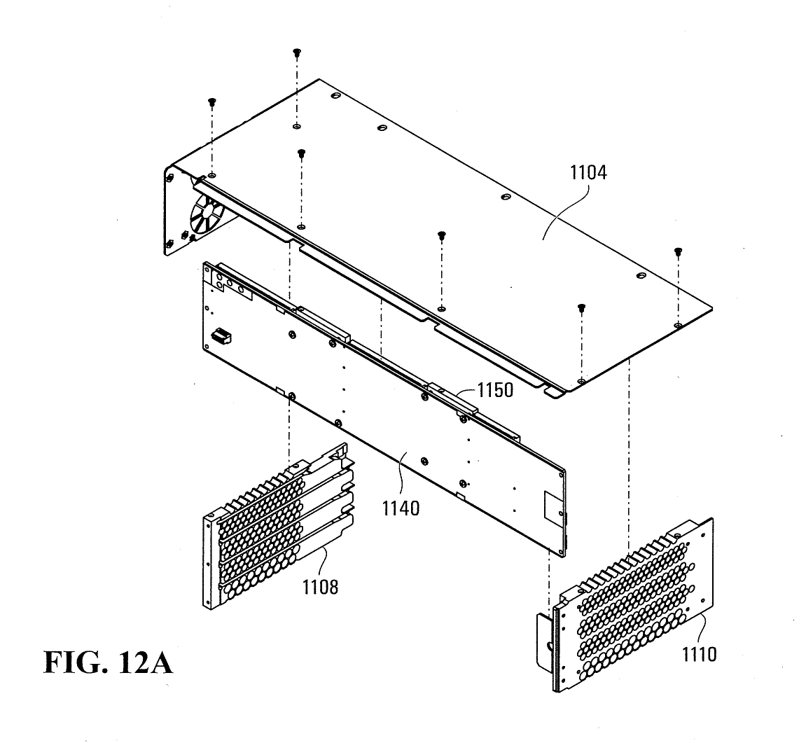

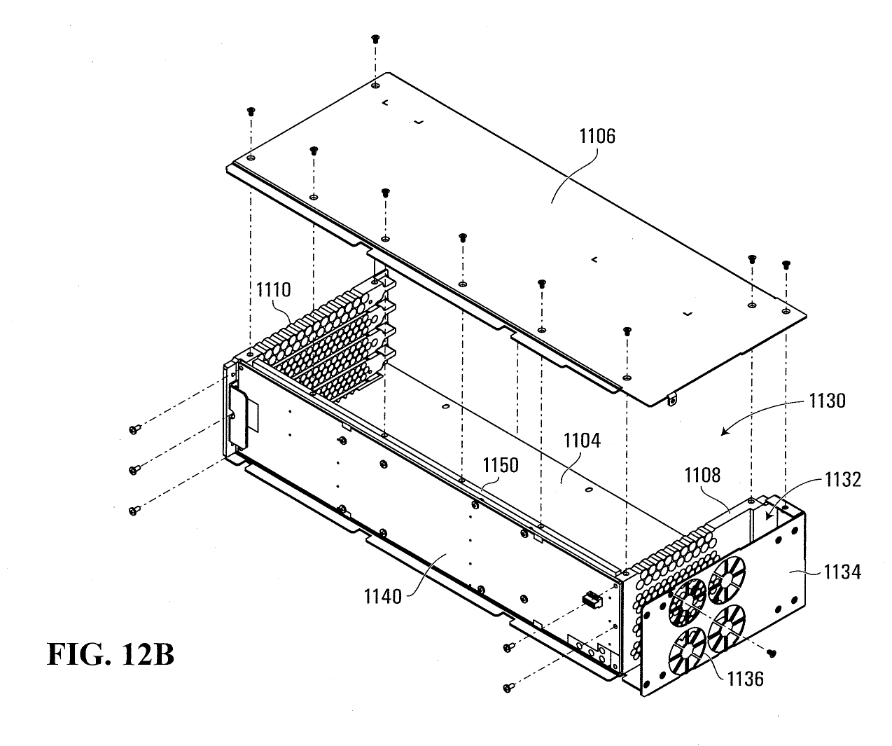

Examples of electronic equipment structural panels and an electronic card are described above. FIGS. 11A and 11B are isometric views and FIGS. 12A and 12B are exploded partial views of example electronic equipment 1100. FIGS. 11A and 11B are rear and front isometric views, respectively. FIG. 12A is an exploded view that includes a bottom housing structural panel 1104, side housing structural panels 1108, 1110, and an electronic card 1140. In FIG. 12A, the components shown in FIG. 12B have been attached together, and the assembled structure has been turned over, for installation of a top housing panel 1104. All of these drawings provide examples of how various bores in various housing panels could be used.

The housing of the example electronic equipment 1100 includes a first pair of structural panels 1104, 1106, and a second pair of structural panels 1108, 1110. The structural panels 1104, 1106 are spaced apart from each other and oriented parallel to each other by the structural panels 1108, 1110. The structural panels 1108, 1110 have integrated card guides facing each other and extending in a direction parallel to a plane of each structural panel 1104, 1106, and also have integrated EMI shielding and thermal cooling structures, in the form of apertures. The structural panels 1104, 1106, however need not include card guides or EMI shielding and thermal cooling structures, and could be fabricated from sheet metal, for example.

There could be other housing components as well. As shown perhaps most clearly in FIG. 12B, the structural panel 1110 has an interior surface facing an electronic card compartment 1130 inside the equipment housing and an exterior surface facing outside the equipment housing. The structural panel 1108, however, has one surface facing the electronic card compartment 1130 and an opposite surface facing another compartment 1132, which accommodates one or more fans in an embodiment. A further panel 1134 completes the housing in the example shown, and includes at least airflow openings, one of which is labelled 1136 in FIGS. 11A and 12B, to provide for airflow through the structural panels 1110 and 1108 all the way through the housing. Thus, the structural panels 1108, 1110 may provide the primary structural support for perpendicular walls 1104, 1106 of the housing and any installed electronic cards, but a housing may include other walls such as 1134 as well.

Electronic equipment could include other components, and not just a housing and one or more electronic cards installed in card guides. For example, there could be another electronic card 1140 oriented perpendicular to the card guides of the structural panels 1108, 1110. The perpendicular electronic card 1140 could include connectors on its inside surface, facing inside the electronic card compartment 1130, for mating with electronic card connectors that are integrated into or carried by an electronic card. Where multiple sets of card guides are provided in the structural panels 1108, 1110, multiple sets of connectors could be provided on the perpendicular electronic card 1140 for mating with corresponding connectors on electronic cards installed using the card guides.

As can perhaps best be appreciated from FIG. 12B, when the housing is assembled, the electronic card compartment 1130 is open at the side which faces the rear in the view shown in the drawing. The opposite side of the housing would also be open, if not for the electronic card 1140. Thus, the electronic card 1140, in effect, covers an opening in the housing even though it is not a housing panel. Similarly, the opposite opening in the housing could be covered by other components as well, such as the cover plate of the electronic card 1160 (FIG. 11A) and the other cover plates 1170, which could be installed to cover electronic card openings in the housing when no electronic cards are installed in one or more card guides. In the example shown, there are card guides for 4 electronic cards, but only one electronic card 1160 is actually installed.

For an electronic card that is installed in the card guides 1122, 1124, thermal cooling could be provided primarily by airflow through the apertures moving over the heat spreader 906 (FIG. 9) and possibly under the printed circuit board 902. Thermal cooling could also or instead be provided for other components as well, such as the perpendicular electronic card 1140. In one embodiment, the ground plane(s) in the printed circuit board(s) of the electronic circuit card 1140 are thermally coupled to or bonded to the structural panels 1108, 1110. Heat transfer from electronic components to the ground plane(s) could be enhanced using one or more heat spreaders or heat pipes, for example. Heat spreaders or heat pipes need not necessarily be used, as there would be some heat transfer from hot components to a printed circuit board or ground plane(s) without such separate thermal conductors, as discussed above with reference to FIGS. 2A and 2B, for example. However, in the example equipment 1100, a heat spreader is shown at 1150, on the inside surface of the electronic card 1140.

A thermal conductor of an electronic card that is thermally coupled to or bonded to the structural panels 1108, 1110 could be in the form of ground plane(s) of a printed circuit board, one or more heat spreaders and/or heat pipe(s), or possibly both. Thermal coupling or bonding could be achieved by using direct contact, or via a thermal interface material.

Other components could also or instead be thermally coupled or bonded to, or otherwise adapted for heat transfer to, the structural panels 1108, 1110. For example, the ground plane(s) of an electronic card could be extended to, and possibly over and around, card edges such as the edges 910, 912 shown in FIGS. 9 and 10. These card edges are at least partially in contact with integrated card guides when an electronic card is installed in electronic equipment, and in this manner heat that is radiated to the ground plane(s) could be transferred to structural panels for dissipation, to further aid in cooling. Electronic cards installed in the card guides could also or instead be otherwise thermally coupled or bonded to the card guides and/or the structural panels.

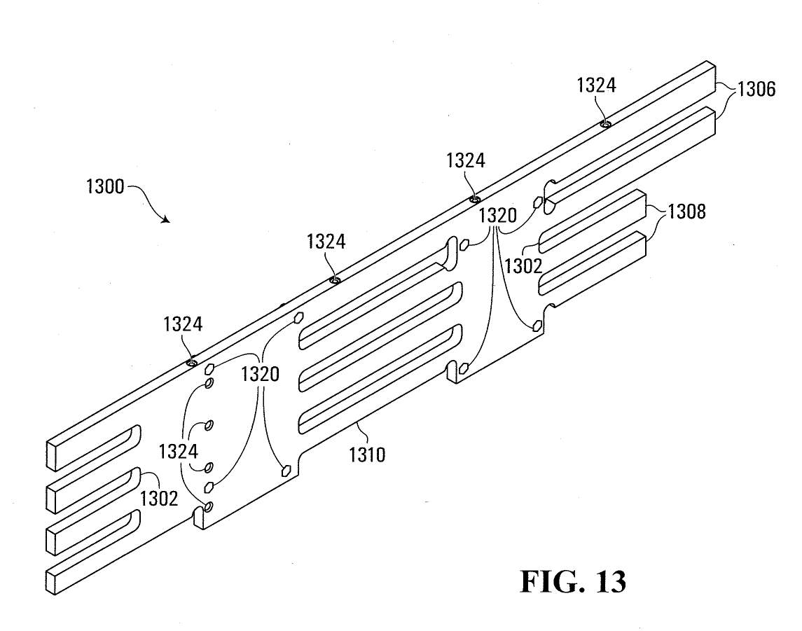

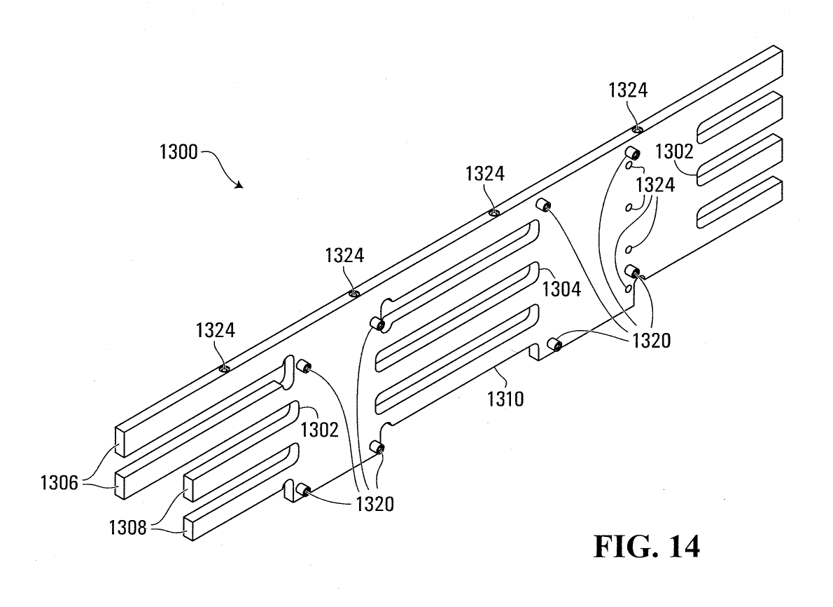

Housing panels as disclosed herein may be used in conjunction with other thermal cooling or heat dissipation arrangements. For instance, FIG. 9 shows a heat spreader 906, and FIGS. 13 and 14 are top and bottom isometric views of another example heat spreader 1300, which could be used as the heat spreader 1150 in FIGS. 12A and 12B.

The example heat spreader 1300 is machined from an aluminum blank in an embodiment, and could be mounted to an electronic card such as the card 1140 (FIGS. 11A, 12A, 12B), for example. In one embodiment, an electronic card to which the example heat spreader 1300 is mounted includes a switching chip on one surface of a printed circuit board, with four rows of connectors and the heat spreader mounted on the opposite surface of the printed circuit board. The heat spreader 1300 aids in dissipating heat from the switching chip that is radiated into the printed circuit board.

In the example shown, the heat spreader 1300 has edge channels or notches 1302, 1310 and internal channels or notches 1304 for accommodating electronic card components, such as four rows of connectors. The “fingers” between edge channels or notches 1302 could be of different lengths as shown at 1306, 1308, to provide clearance for accommodating other components. The design and layout of a heat spreader is implementation-specific, and depends on the particular components to be cooled.

The view shown in FIG. 13 is a “top” view of the example heat spreader 1300, in that the surface toward the front of the drawing would be oriented away from a printed circuit board to which the heat spreader is to be attached or mounted. The view shown in FIG. 14 is a “bottom” view, showing the surface that would be facing the printed circuit board. Fasteners are received in the posts 1320 to attach the heat spreader 1300 to the printed circuit board. The posts 1322 could instead be attached to the printed circuit board, as in the case of the example electronic card 900 (FIG. 10). Additional bores could also be provided, as shown at 1324, to attach the heat spreader 1300 to other components and/or to mount other components to the heat spreader. The bores 1324 along the top of the heat spreader 1300 in the view shown in FIG. 13, for example, and bores along the bottom of the heat spreader (not shown) could be used to attach the housing structural panel 1104 to the heat spreader, as shown in FIGS. 12A and 12B.

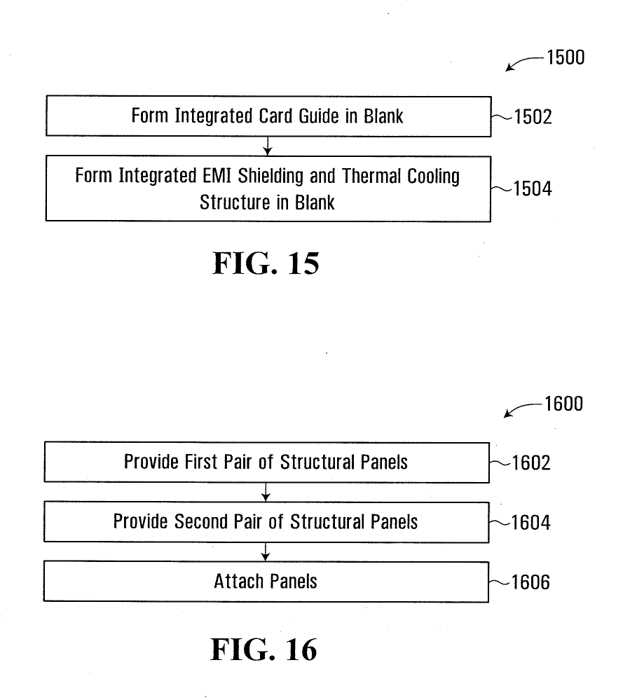

FIGS. 2 to 14 illustrate various embodiments in apparatus form. Method embodiments are also contemplated. FIGS. 15 and 16 are flow charts of example methods.

The example method 1500 illustrated in FIG. 15 relates to manufacturing of an electronic equipment housing structural panel. As shown at 1502, the example method 1500 involves forming, in a blank of material for the electronic equipment housing structural panel, an integrated electronic card guide. At 1504, there is another forming operation to form, in the blank of material, an integrated EMI shielding and thermal cooling structure. The blank of material could be aluminum, illustratively a blank of ¼-inch thick aluminum. Other materials, such as steel or plastic, could instead be used. Aluminum may be preferred for its relatively light weight compared to other metals and its thermal conduction properties. An implementation that is intended to use only the integrated card guide features disclosed herein could potentially use plastic structural panels, although a plastic that is coated or impregnated with a metal or other thermal conductor could also potentially be used to manufacture structural panels with integrated EMI and thermal cooling structures as well.

The forming at 1502 could involve forming multiple integrated electronic card guides in the blank of material. In one embodiment, the forming at 1502 includes machining the integrated electronic card guide(s) in the blank of material.

Forming the integrated EMI and thermal cooling structure could similarly involve machining, such as machining apertures in the blank of material. Such machining processes as punching the apertures in the blank of material or drilling the apertures in the blank of material could be used. Laser cutting the apertures in the blank of material is another possible option.

In a preferred embodiment, the fabrication of a structural panel with integrated grooves for card guides and apertures for airflow and EMI suppression involves machining of metal, and in particular aluminum. In a machining process, all dimensional aspects of a workpiece can be controlled to very high tolerance. This can potentially improve EMI performance by reducing the dimensions of unwanted gaps where metal parts contact. A high-tolerance manufacturing process could also allow for higher dimensional precision in the card guides themselves, which may in turn provide for superior accuracy in blind-mating of electronic cards in a chassis.

Although machining of metal is a currently preferred manufacturing process, other processes are possible. Structural panels could be cast, for example. In the case of plastic-based structural panels, for example, extrusion is also an option. An extrusion process could produce an extrudate having the EMI/cooling apertures formed along the extrusion direction, and the extrudate could be sliced into cross-sections into which the card guide(s) would then be formed. However, since machining may provide for higher precision control of physical dimensions, machining of metal may generally be preferred over other manufacturing processes.

The example method 1600 in FIG. 16 relates to assembling or building an electronic equipment housing. Reference is also made to FIGS. 12A and 12B to further illustrate assembly of an electronic equipment housing. At 1602, a first pair of structural panels (for example, 1104, 1106) is provided, and a second pair of structural panels (for example, 1108, 1110) is provided at 1604. These operations could involve manufacturing the structural panels, but it should be appreciated that the panels could otherwise be provided, by purchasing them from a manufacturer for example. Each structural panel (1108, 1110) in the second pair of structural panels includes an integrated electronic card guide formed in the panel, and an integrated EMI shielding and thermal cooling structure formed in the structural panel. The first pair of panels (1104, 1106) provided at 1602 could be sheet metal panels, as shown in FIGS. 11A, 11B, 12A and 12B, for example, and need not include card guides or EMI shielding and thermal cooling structures.

At 1606, the structural panels (1104, 1106) in the first pair are attached to the structural panels (1108, 1110) in the second pair. The panels are attached so that the structural panels (1104, 1106) in the first pair are spaced apart from each other and oriented parallel to each other by the structural panels (1108, 1110) in the second pair, and the card guides in the structural panels (1108, 1110) in the second pair face each other and extend in a direction parallel to a plane of each structural panel (1104, 1106) in the first pair. The structural panels (1104, 1106, 1108, 1110) could be attached to each other using screws or other fasteners, and bores in the structural panels, for example. As will be apparent from FIGS. 12A and 12B, for example, both of the structural panels 1108, 1110 could be attached to one of the structural panels 1104 of the first pair, and then subsequently attached to the other structural panel 1106 of the first pair. A different order of assembly is possible in other embodiments.

The example method 1600 forms an equipment housing. An electronic card may then be installed into the card guides of the second pair of structural panels. Electronic card installation could be performed at a different time and/or by a different entity than the housing assembly operations shown in FIG. 16. For instance, an equipment manufacturer might assemble a housing and install one or more electronic cards, but it is also possible to have a housing manufacturer assemble a housing and then provide the assembled housing to another entity for installation of the electronic card(s).

As noted above with reference to FIGS. 11A, 12A, and 12B, a further electronic card such as the electronic card 1140 could be installed in electronic equipment and thermally coupled to or bonded to structural panels of a housing. Thus, there could be an additional operation of thermally coupling a further electronic card to the second pair of structural panels. In an embodiment, such a further electronic card is in an orientation perpendicular to the card guides, but this is just an example. An electronic card in a different orientation could be thermally coupled to or bonded to the structural panels.

The example methods 1500 and 1600 are illustrative of embodiments. Examples of additional operations that may be performed will be apparent from FIGS. 2 to 13 and the descriptions thereof, for example. Operations could also or instead be performed in a different order than shown. In FIG. 15, for example, the card guide(s) need not necessarily be formed at 1502 before the integrated EMI shielding and thermal cooling structures are formed at 1504. Further variations may be or become apparent.

As described in detail herein, a single structural panel of an equipment housing could act as an EMI shield, electronic card guide, and thermal heat spreader with airflow paths. The airflow paths provide for not only airflow but also EMI suppression. In some embodiments, the thermal mass of a structural panel and large surface area of the apertures work together to provide for heat transfer from the panel to the air.

By combining the functions of EMI suppression, heat dissipation, and electronic card guide into a single part, overall cost could be reduced relative to systems in which separate components provided for each of these features.

What has been described is merely illustrative of the application of principles of embodiments of the present disclosure. Other arrangements and methods can be implemented by those skilled in the art.

For example, the contents of the drawings are intended solely for illustrative purposes. Embodiments of the present invention are not in any way limited to the particular example embodiments explicitly shown in the drawings and described herein.

It should also be appreciated that electronic card guide features and EMI shielding/suppression and thermal cooling/heat dissipation features need not necessarily be implemented in combination in every embodiment. An electronic equipment housing structural panel could include an integrated electronic card guide formed in the structural panel, without also necessarily including EMI shielding/suppression and thermal cooling/heat dissipation structures.

Circular apertures are disclosed herein by way of example. Other aperture shapes may also or instead be used. Rectangular or square apertures are noted above as illustrative examples of different shapes.

We claim:

1. An electronic equipment housing structural panel, comprising:
an integrated electronic card guide formed in the structural panel; and
an integrated ElectroMagnetic Interference (EMI) shielding and thermal cooling structure formed in the structural panel.

2. The electronic equipment housing structural panel of claim 1, comprising a plurality of integrated electronic card guides formed in the structural panel.

3. The electronic equipment housing structural panel of claim 2, wherein the plurality of integrated electronic card guides comprise respective channels formed in respective card guide areas of the structural panel, wherein the integrated EMI and thermal cooling structure is formed in an area of the structural panel different from the respective card guide areas.

4. The electronic equipment housing structural panel of claim 1, comprising a plurality of integrated EMI and thermal cooling structures formed in the structural panel.

5. The electronic equipment housing structural panel of claim 4, wherein the integrated EMI and thermal cooling structures comprise respective sets of apertures formed in the structural panel.

6. The electronic equipment housing structural panel of claim 5, wherein each of the apertures has a depth of 11.5 mm and a diameter in a range of 5.5 mm to 8.0 mm.

7. The electronic equipment housing structural panel of claim 5, wherein each aperture has an axial surface area of at least 198.7 mm².

8. The electronic equipment housing structural panel of claim 5, wherein each of the sets of apertures is formed in a respective area of the structural panel, wherein an aperture density of each of the sets of apertures is at least 65% of a total surface area of the respective area.

9. An electronic equipment housing comprising:
a first pair of structural panels;
a second pair of structural panels;
wherein the structural panels in the first pair of structural panels are spaced apart from each other and oriented parallel to each other by the structural panels in the second pair of structural panels,
wherein each of the structural panels in the second pair of structural panels comprises an electronic equipment housing structural panel of claim 1, with the card guides in the structural panels in the second pair of structural panels facing each other and extending in a direction parallel to a plane of each structural panel in the first pair of structural panels.

10. Electronic equipment comprising:
the electronic equipment housing of claim 9; and
an electronic card installed in the card guides of the structural panels in the second pair of structural panels.

11. The electronic equipment of claim 10, further comprising:
a further electronic card comprising a thermal conductor coupled to the structural panels in the second pair of structural panels.

12. The electronic equipment of claim 11, further comprising one or both of:
a heat spreader attached to the electronic card; and
a further heat spreader attached to the further electronic card.

13. The electronic equipment of claim 11, wherein the further electronic card comprises a printed circuit board, and wherein the thermal conductor coupled to the structural panels in the second pair of structural panels comprises one or more of:
an exposed copper plane on a surface of the printed circuit board;
internal ground planes in the printed circuit board;
vias in the printed circuit board;
fasteners that fasten the further electronic card to the structural panels in the second pair of structural panels.

14. A method of manufacturing an electronic equipment housing structural panel, comprising:
forming, in a blank of material for the electronic equipment housing structural panel, an integrated electronic card guide; and
forming, in the blank of material, an integrated ElectroMagnetic Interference (EMI) shielding and thermal cooling structure.

15. The method of claim 14, wherein forming the integrated electronic card guide comprises machining the integrated electronic card guide in the blank of material.

16. The method of claim 14, wherein forming the integrated electronic card guide comprises forming a plurality of integrated electronic card guides in the blank of material.

17. The method of claim 14, wherein forming the integrated EMI and thermal cooling structure comprises machining apertures in the blank of material.

18. The method of claim 17, wherein the machining comprises one of: punching the apertures in the blank of material, drilling the apertures in the blank of material and laser cutting the apertures in the blank of material.

19. A method comprising:
providing a first pair of structural panels;
providing a second pair of structural panels, each structural panel in the second pair of structural panels comprising: an integrated electronic card guide formed in the panel, and an integrated ElectroMagnetic Interference (EMI) shielding and thermal cooling structure formed in the structural panel;
attaching the structural panels in the first pair of structural panels to the structural panels in the second pair of structural panels with the structural panels in the first pair of structural panels spaced apart from each other and oriented parallel to each other by the structural panels in the second pair of structural panels, and the electronic card guides in the structural panels in the second pair of structural panels facing each other and extending in a direction parallel to a plane of each structural panel in the first pair of structural panels.

20. The method of claim 19, further comprising:
installing an electronic card into the electronic card guides of the structural panels in the second pair of structural panels.

21. The method of claim 20, further comprising:
thermally coupling a further electronic card to the structural panels in the second pair of structural panels, in an orientation perpendicular to the electronic card guides of the structural panels in the second pair of structural panels.

22. An electronic equipment housing structural panel comprising an integrated electronic card guide formed in the structural panel.
